(19) United States
(12) Patent Application Publication
(10) Pub. No.: US 2002/0180052 A1
(43) Pub. Date: Dec. 5, 2002

(54) Polish or etch stop layer

(76) Inventors: Nace Layadi, Singapore (SG); Simon John Molloy, Allentown, PA (US)

Correspondence Address: BEUSSE, BROWNLEE, BOWDOIN & WOLTER, P. A., 390 NORTH ORANGE AVENUE, SUITE 2500, ORLANDO, FL, 32801, US

(21) Appl. No.: 09/905,398

(22) Filed: Jul. 14, 2001

Related U.S. Application Data
(60) Provisional application No. 60/295,996, filed on Jun. 5, 2001.

(51) Int. Cl. H01L 23/48

(52) U.S. Cl. 257/763

(57) ABSTRACT

An improved polish stop or etch stop material for use in semiconductor device manufacturing. An alloy of titanium nitride having an increased hardness when compared to the prior art titanium nitride material is selected to reduce the material removal rate during chemical mechanical polishing (CMP) or plasma etching processes. Titanium nitride may be alloyed with aluminum to form titanium aluminum nitride (TiAlN) for use as either a polish stop material or an etch stop material. Titanium nitride may be alloyed with carbon to form titanium carbon nitride (TiCN) for use as a polish stop material. In a preferred embodiment, the amount of aluminum or carbon added to the titanium nitride is between about 5 and 20 percent by weight, thereby increasing the hardness of the stop material by about 30-35 percent when compared to titanium nitride alone.

This application claims the benefit of the Jun. 5, 2001, filing date of U.S. provisional patent application serial No. (not yet assigned).

### FIELD OF THE INVENTION

The present invention relates to microelectronic devices and, more particularly, to compositions for polish stop layers and etch stop layers in such devices.

### BACKGROUND OF THE INVENTION

Microelectronic devices, such as ultra large scale integrated (ULSI) circuits, are commonly formed as multi-layered devices having alternating layers of conductors and dielectric material. Each of these layers is deposited separately and often the layers are polished to a high degree of planarity prior to the deposition of an overlying layer. Chemical mechanical polishing (CMP) is the leading process used to produce planar multi-layer metallization systems in modern ULSI circuits.

Prior to depositing a metal interconnect or conductor layer, a relatively thick dielectric layer is deposited over a substrate and any integrated circuit devices formed on the substrate. The dielectric layer is then polished using a chemically active slurry and a polishing pad to produce a very flat or planar surface. Contact holes or vias are etched in the dielectric material. A barrier metal and a tungsten film are then deposited over the etched dielectric in order to fill the vias. The tungsten film is then polished off the surface leaving a flat surface with the contact holes or vias filled with plugs of the barrier metal and tungsten. The metal interconnect layer is then deposited over the polished dielectric layer, forming electrical connection with the tungsten plugs.

Removal of the tungsten film from the dielectric surface to form the via plugs commonly employs a CMP process. This process must remove the tungsten film from the surface without polishing away too much of the underlying dielectric and without adding non-uniformity to the dielectric thickness. For this reason, titanium nitride (TiN) is generally used as a barrier metal and adhesion layer over the dielectric layer prior to the deposition of the tungsten material so that the TiN acts as a polish stop layer protecting the underlying dielectric layer. The CMP process is then used to remove all the tungsten from the surface of the TiN layer but leave the vias or contact holes filled with the tungsten plugs. Commonly, over-polishing is required to ensure that the tungsten is cleared from all of the titanium nitride surface. During this over polishing step, portions of the TiN layer may be completely removed such that some of the dielectric underneath the TiN layer is also removed. Accordingly, the TiN layer is sometimes ineffective in isolating the polishing action from the dielectric layer.

In addition to its use as a polish stop layer, TiN is also used as an anti-reflective coating in the metallization of ULSI devices to aid in the patterning of aluminum-based metal films. In such applications, the TiN layer is deposited on the metal film where it also functions to prevent the formation of mounds or rises on the surface of the aluminum-based metal film. During the construction of the device, after application of a dielectric over the aluminum and TiN layers, plasma etching is used to form contact holes or vias through the dielectric. It is desirable that the etching process stop when the TiN layer is reached and that it not penetrate into the aluminum layer. However, in the construction of the device, there may be areas in which the vias are shallow and are subjected to a large amount of over-etch to ensure that deeper vias in other areas are fully open. Careful selection of the dielectric, such as silicon dioxide when used with TiN, is required to prevent over-etching in the shallow vias. Often, compromises in the profile of the via or its selectivity to resist have to be made in order to prevent over-etching. However, different types of etching processes and chemistries often result in penetration through the TiN layer due to a lack of selectivity to the particular etch process. Accordingly, it is desirable to provide an improved anti-reflective coating which has a higher selectivity to the via etch process.

### SUMMARY OF THE INVENTION

The present invention provides an improved stop layer for both chemical mechanical polishing and plasma etching processes used in ULSI fabrication.

A chemical mechanical polish (CMP) stop layer for use in a semiconductor manufacturing process is described herein as comprising one of titanium aluminum nitride (TiAlN) and titanium carbon nitride (TiCN) disposed over an underlying substrate for stopping a CMP process from compromising the underlying substrate. The CMP stop layer may included between 5 and 20 percent by weight of aluminum or between 5 and 20 percent by weight of carbon.

A plasma etch stop layer for use in a semiconductor manufacturing process is also described here as comprising titanium aluminum nitride (TiAlN) disposed over an underlying layer for stopping an etch process from compromising the underlying layer. The plasma etch stop layer may include between 5 and 20 percent by weight of aluminum.

A method of forming a metal interconnect in a semiconductor device is described herein as comprising: depositing a dielectric layer over a substrate; forming a contact hole in the dielectric layer; depositing a polish stop layer comprising one of titanium aluminum nitride (TiAlN) and titanium carbon nitride (TiCN) over the dielectric layer; depositing a layer of metal over the polish stop layer and filling the contact hole; exposing a top surface of the layer of metal to a chemical mechanical polishing (CMP) process to remove that portion of the layer of metal disposed over the dielectric layer and leaving a flat surface with the contact hole filled with a plug of the layer of metal, the polish stop layer preventing the CMP process from removing any portion of the dielectric layer. The polish stop layer may be deposited to have between about 5 and 20 percent by weight of aluminum or carbon. The method may further include removing at least a portion of the polish stop layer by exposing the polish stop layer to a chlorine-containing plasma etch that is selective to the underlying dielectric layer.

A method of forming a microelectronics device is further described herein as including: disposing a layer of metal over a substrate; depositing an etch stop layer comprising titanium aluminum nitride (TiAlN) over the layer of metal; depositing a dielectric layer over the etch stop layer; forming a patterned photoresist layer on the dielectric layer; using an etch process to remove those portions of the dielectric layer exposed through the photoresist layer pattern; and wherein the etch process is stopped by the etch stop layer so that no portion of the layer of metal is removed. The method may further include depositing the etch stop layer to comprise TiAlN having between 5 and 20 percent by weight of aluminum.

### BRIEF DESCRIPTION OF THE DRAWINGS

The features and advantages of the present invention will become apparent from the following detailed description of the invention when read with the accompanying drawings in which:

FIG. 1 is a partial cross-sectional view of a microelectronic device at a stage of fabrication where an improved CMP stop layer and layer of tungsten are deposited over a dielectric layer having a via formed therein.

FIG. 2 is the device of FIG. 1 after it has undergone a chemical mechanical polishing step which has terminated at the improved stop layer without disturbing the dielectric layer.

FIG. 3 is a partial cross-sectional view of a microelectronic device at a stage of fabrication where an improved etch stop layer is deposited between a dielectric layer and an aluminum layer.

FIG. 4 is the device of FIG. 3 after it has undergone a via etching process which has terminated at the improved stop layer without disturbing the aluminum layer.

### DETAILED DESCRIPTION OF THE INVENTION

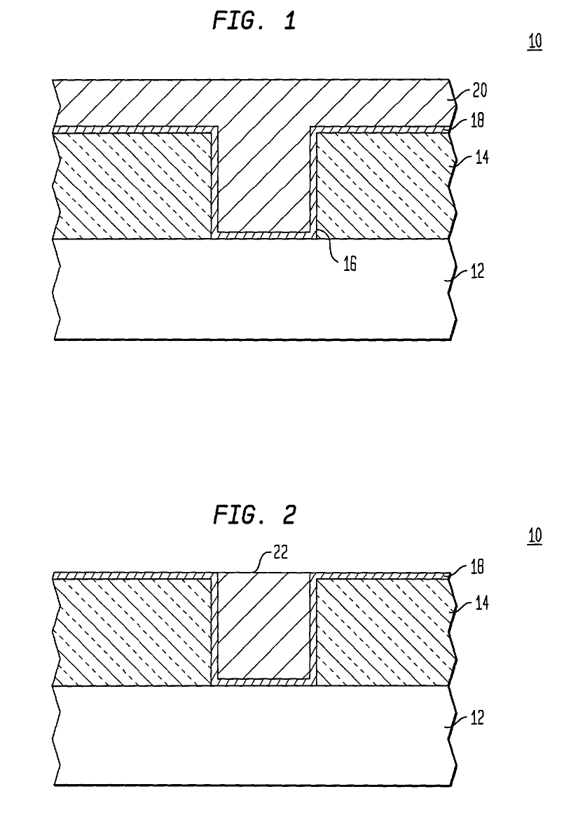

Various processes are known in the art for creating microelectronics devices. One such process is illustrated in U.S. Pat. No. 6,008,123 to which reference may be made for more details of the manufacturing process. FIG. 1 herein is a simplified cross-sectional view of a portion of a microelectronics device 10 similar to that shown in the '123 patent. The device 10 includes a substrate layer 12 that has been polished using conventional polishing processes, and a dielectric layer 14 deposited directly on the substrate layer 12. A via 16 has been etched through the dielectric 14 to provide for receipt of a metallic interconnect to the substrate layer 12. Once the dielectric layer 14 has been etched and planarized, a polish stop layer 18 is deposited over the dielectric layer. The polish stop layer 18 may be disposed only over the top surface of the dielectric layer 14 or preferably may also be deposited into the via 16. Thereafter, a tungsten film or layer 20 is deposited over the polish stop layer 18 with the tungsten filling the via 16 to provide the metallic interconnect to the substrate layer from a layer (not shown) to be formed above the dielectric layer 14. The substrate may be typically TEOS or silicon dioxide.

FIG. 2 illustrates the structure of the device 10 after chemical mechanical polishing (CMP) of the device to remove a portion of the tungsten film 20. The CMP process typically employs an abrasive such as aluminum oxide and an oxidizer such as ferric nitrate to abrade and chemically remove surface material. The CMP process removes the film 20 disposed over the dielectric layer 14 while leaving a tungsten plug 22 filing the via 16. In the present invention, the polish stop layer 18 is formed from a hardened alloy material that resists CMP better than the prior art titanium nitride stop material. Preferably, the layer 18 comprises titanium nitride (TiN) alloyed with either carbon or aluminum to form titanium carbon nitride (TiCN) or titanium aluminum nitride (TiAlN) respectively. The addition of carbon or aluminum to TiN can provide a significant increase in hardness. The inventors have found that an effective polish stop layer for the CMP process can be formed from TiN alloyed with between about 5 and 20 percent by weight of carbon or aluminum. As shown in FIG. 2, this alloy is sufficiently hard to withstand over-polishing of the tungsten layer so that the polish stop layer 18 is not penetrated and no portion of the dielectric layer 14 is removed or compromised.

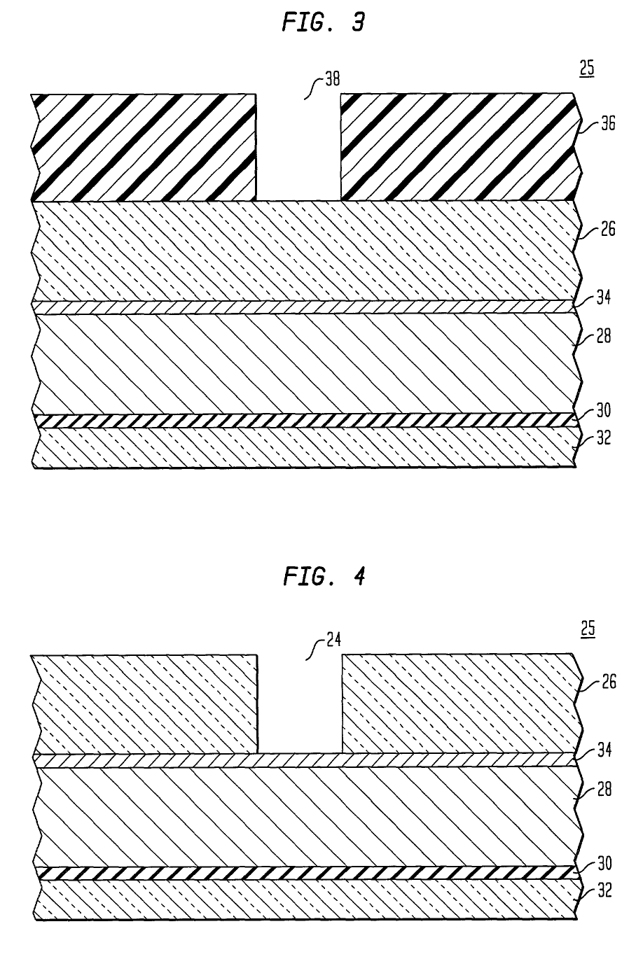

FIGS. 3 and 4 illustrate further steps in the process of manufacturing a microelectronics device 25 in which a via 24 is etched through a dielectric layer 26 to provide a connection to an underlying metal layer 28. One may appreciate that the structures illustrated in FIGS. 2 and 4 may be formed independently, or they may be formed together in the same microelectronic device. The metal layer 28 is typically aluminum but alternatively could be a tungsten layer as illustrated in FIG. 2. An unprotected aluminum layer 28 would be subject to etching by the etching process that is used to create the via 24 through the dielectric layer 26. The illustrated device avoids this potential problem as will be described more fully below. A barrier layer 30 typically formed of TiN overlays a dielectric layer 32. The metallic layer 28 overlays the TiN layer 30. An etch stop layer 34 formed of TiN alloyed with aluminum to form TiAlN is deposited over the metal layer 28 to protect layer 28 from being etched. The aluminum added to the TiN gives the material a more ceramic nature and accordingly makes it harder and more resistive to the plasma etch process than TiN alone. It will be recognized by persons skilled in the art that the various layers described herein may be measured in fractions of microns in thickness so that any breakthrough of a stop layer may result in significant deterioration of a layer to be protected. The addition of aluminum to titanium nitride in the manner described herein results in a substantially harder etch or polish resistant layer than prior art TiN layers. For applications of an etch stop layer the TiN is not alloyed with carbon, as it may be in the CMP process stop layer described above, since the carbon would be readily etched in conventional SiO₂ etch chemistries or in O₂ plasma resist strip.

Again referring to FIG. 3, the dielectric layer 26 overlays the etch stop layer 34. A photoresist mask 36 is formed over the layer 26 using conventional processes so as to create holes 38 at locations where vias are to be etched through dielectric layer 26. FIG. 4 shows the resultant product after via etching and photoresist removal. The via 24 has been formed fully through the dielectric layer 26 and the etch process has stopped at the TiAlN etch stop layer 34 without disturbance of the underlying metal layer 28.

The polish stop layer 18 and etch stop layer 34 described herein may be removed using a chlorine-containing plasma etch that is selective to the underlying material, i.e. the chlorine plasma etch will remove the titanium nitride alloy without attacking the underlying dielectric or metallic layer.

The inventors have found that the alloy of titanium nitride with either carbon or aluminum creates a material having a hardness which is 30 to 35 percent greater than titanium nitride alone. Accordingly, the TiAlN or TiCN alloys have greater resistance to the subsequent CMP and/or etching process and provide an improved combination for use in manufacturing of semiconductor devices, particularly as the thickness of the layers in such devices become thinner.

While the preferred embodiments of the present invention have been shown and described herein, it will be obvious that such embodiments are provided by way of example only. Accordingly, it is intended that the invention be limited only by the spirit and scope of the appended claims.

We claim as our invention:

1. A semiconductor structure comprising:
a substrate having a device feature formed thereon;
a dielectric layer disposed over said substrate and device feature and having at least one contact hole formed therein;
a polish stop layer disposed over the dielectric layer and within the contact hole;
a layer of tungsten disposed over the polish stop layer within the contact hole and forming a plug; and
wherein said polish stop layer comprises one of titanium aluminum nitride (TiAlN) and titanium carbon nitride (TiCN).

2. The semiconductor structure of claim 1 and including a metal coating under said dielectric layer, said metal coating comprising a compound of TiN and aluminum.

3. The semiconductor structure of claim 2 wherein the dielectric comprises silicon dioxide (SiO₂).

4. The semiconductor structure of claim 3, wherein the metal coating comprises an anti-reflective coating.

5. The semiconductor structure of claim 1, wherein the barrier layer comprises TiAlN with between about 5 and 20 percent by weight of aluminum.

6. The semiconductor structure of claim 1, wherein the barrier layer comprises TiCN with between about 5 and 20 percent by weight of carbon.

7. The semiconductor structure of claim 2, wherein the metal coating comprises about 5 to 20 percent by weight of aluminum.

8. A chemical mechanical polish (CMP) stop layer for use in a semiconductor manufacturing process comprising one of titanium aluminum nitride (TiAlN) and titanium carbon nitride (TiCN) disposed over an underlying substrate for stopping a CMP process from compromising the underlying substrate.

9. The CMP stop layer of claim 8, further comprising TiAlN having between 5 and 20 percent by weight of aluminum.

10. The CMP stop layer of claim 8, further comprising TiCN having between 5 and 20 percent by weight of carbon.

11. A plasma etch stop layer for use in a semiconductor manufacturing process comprising titanium aluminum nitride (TiAlN) disposed over an underlying layer for stopping an etch process from compromising the underlying layer.

12. The plasma etch stop layer of claim 11, further comprising TiAlN having between 5 and 20 percent by weight of aluminum.

13. A method of forming a metal interconnect in a semiconductor device, the method comprising:
depositing a dielectric layer over a substrate;
forming a contact hole in the dielectric layer;
depositing a polish stop layer comprising one of titanium aluminum nitride (TiAlN) and titanium carbon nitride (TiCN) over the dielectric layer;
depositing a layer of metal over the polish stop layer and filling the contact hole;
exposing a top surface of the layer of metal to a chemical mechanical polishing (CMP) process to remove that portion of the layer of metal disposed over the dielectric layer and leaving a flat surface with the contact hole filled with a plug of the layer of metal, the polish stop layer preventing the CMP process from removing any portion of the dielectric layer.

14. The method of claim 13, further comprising depositing the polish stop layer to have between about 5 and 20 percent by weight of aluminum.

15. The method of claim 13, further comprising depositing the polish stop layer to have between about 5 and 20 percent by weight of carbon.

16. The method of claim 13, further comprising removing at least a portion of the polish stop layer by exposing the polish stop layer to a chlorine-containing plasma etch that is selective to the underlying dielectric layer.

16. A method of forming a microelectronics device, the method comprising:
disposing a layer of metal over a substrate;
depositing an etch stop layer comprising titanium aluminum nitride (TiAlN) over the layer of metal;
depositing a dielectric layer over the etch stop layer;
forming a patterned photoresist layer on the dielectric layer;
using an etch process to remove those portions of the dielectric layer exposed through the photoresist layer pattern; and
wherein the etch process is stopped by the etch stop layer so that no portion of the layer of metal is removed.

17. The method of claim 16, further comprising depositing the etch stop layer to comprise TiAlN having between 5 and 20 percent by weight of aluminum.
